(19) United States
(12) Patent Application Publication
(10) Pub. No.: US 2019/0214340 A1
(43) Pub. Date: Jul. 11, 2019

(54) POWER MODULE

(71) Applicant: SIEMENS AKTIENGESELLSCHAFT, München (DE)

(72) Inventors: Michael Leipenat, Pommelsbrunn (DE); Christoph Nöth, Nürnberg (DE); Ralf Schmidt, Nürnberg (DE); Ronny Werner, Nürnberg (DE)

(21) Appl. No.: 16/330,845

(22) PCT Filed: Jul. 7, 2017
(86) PCT No.: PCT/EP2017/067094

§ 371 Date: Mar. 6, 2019

(30) Foreign Application Priority Data
Sep. 7, 2016 (DE) 10 2016 217 007.4

(51) Int. Cl. H01L 23/498; H01L 23/00

(52) U.S. Cl. CPC H01L 23/49838; H01L 24/72; H01L 23/49861

(57) ABSTRACT

The disclosure relates to a power module including a semiconductor component configured to be contacted on the top side and the underside. The semiconductor component is configured to be electrically contacted on the top side by a leadframe matrix by contact pressure.

The present patent document is a § 371 nationalization of PCT Application Serial No. PCT/EP2017/067094, filed Jul. 7, 2017, designating the United States, which is hereby incorporated by reference, and this patent document also claims the benefit of German Patent Application No. DE 10 2016 217 007.4, filed Sep. 7, 2016, which is also hereby incorporated by reference.

### TECHNICAL FIELD

The disclosure relates to a power module having a carrier element, the underside of which is arranged on a metal layer and the upper side of which includes a contact element, wherein a semiconductor component is positioned on the contact element.

### BACKGROUND

In the present case, the particular focus involves power modules which are employed in the field of power electronics. The field of power electronics customarily concerns the conversion of electrical energy by switching semiconductor components. These semiconductor components, which are also described as power electronic components, may be configured, for example, as power diodes, power metal-oxide semiconductor field-effect transistors (MOSFETs), or insulated-gate bipolar transistors (IGBTs). To this end, one or more semiconductor components, which are also described as chips, are arranged on a substrate, thereby constituting a “power module”. The substrate, upon which the semiconductor component(s) is (are) secured by a mounting arrangement and a connecting technology, may also be employed for the electrical connection of the semiconductor components. Substrates of this type may include, for example, a carrier element of a ceramic material which, for the electrical contacting and mechanical attachment of the semiconductor components, is coated with printed conductors and electrical contact elements, which are constituted, for example, of copper.

Semiconductor components which are interconnected to constitute power modules may, for example, execute current conversion functions, and may be employed in the field of electromobility, for example, in the drive systems of electric vehicles. Specifically, in the field of electromobility, stringent requirements apply to the operating time and the service life of power modules. In particular, power modules using the mounting and connecting technology employed to date fail to achieve the requisite operating time and service life.

In particular, for the electrical contacting of semiconductor components on the upper side, it is necessary to establish a reliable electrical connection, and thus a flow of current to the terminals or contact elements. The properties of electrical connections between the upper side of the semiconductor component or chip and a contact element of the substrate frequently limit the durability of the power module. From the prior art, for example, it is known for corresponding heavy-gauge aluminum wires to be employed for these electrical connections, which are bonded to the semiconductor component and to the contact element. Newer technologies involve, for example, heavy-gauge copper wire bonds or “strip bonds”. Other solutions involve sintered and metal-plated synthetic films. Soldered conductor rails of heavy-gauge copper construction are also known. “SiPLIT” technology (Siemens Planar Interconnect Technology) is moreover known.

All these solutions have a disadvantage, in that the coefficients of thermal expansion of the materials employed deviate substantially from the coefficients of thermal expansion of the substrate and the semiconductor component. Thus, during operation, severe mechanical stresses occur between the boundary layers which, in turn, may lead to the failure of the power module.

### SUMMARY AND DESCRIPTION

The scope of the present disclosure is defined solely by the appended claims and is not affected to any degree by the statements within this summary. The present embodiments may obviate one or more of the drawbacks or limitations in the related art.

The object of the present disclosure is the provision of a power module with improved electrical contacting of the semiconductor component.

This object is fulfilled by a power module. The power module includes a carrier element, the underside of which is arranged on a metal layer and the upper side of which includes a contact element, wherein a semiconductor component is positioned on the contact element. The semiconductor component is configured to be electrically contacted on the top side by a leadframe matrix by contact pressure.

For the relief of strain on the connection point between the top side of the chip and the leadframe, the leadframe is only intended to be pressed against the top side of the chip, and is not permanently attached thereto, for example, by sintering. According to current practice, the leadframe includes a plurality of mutually separated printed copper conductors. The leadframe printed conductors are encapsulated in a matrix material such as, for example, on an epoxy resin, prior to assembly. The matrix material has both the property of the retention of the printed copper conductors of the leadframe in position, thereby defining accurate contact positions, and of the maintenance of electrical insulation between the printed conductors. The uninsulated leadframe partially projects out of the matrix material, for the purposes of contacting at the top and bottom. For this contacting on the underside, a specific compression force is applied to the top side of the chip. This means that a specific force is applied to the matrix material, which is intended to provide permanent contacting between the leadframe and the chip. It is also possible for the leadframe to be firstly inserted in a plastic housing, and encapsulated in a matrix thereafter. This combination of the plastic housing and the leadframe is pressed onto the PCB at a later stage, elastically bonded and filled with an electrically-insulating soft resin mass.

The encapsulated leadframe permits ease of handling, as the mutually separated leadframe printed conductors are arranged in a matrix material. The leadframe is moreover protected by the matrix material, and may withstand low to moderate external forces. The resulting assembly is thus more robust. Additionally, it is not necessary for the leadframe to be directly pressed onto each individual chip. By the application of a specific pressure to the matrix material, the force is distributed evenly between the contact points. An advantage over the soldering or sintering of connecting elements is provided by the employment of standard chip surfaces. As a result, cost-effective semiconductors may be employed. Moreover, the leadframe is not permanently bonded to the chip, such that the latter is exempt from thermal stresses.

In a further development, the leadframe matrix may be constituted of a plurality of mutually separate printed conductors.

According to a specific configuration of this concept, the printed conductors are printed copper conductors.

According to an advantageous configuration of the concept, the printed conductors may be formed by encapsulation in a matrix material, prior to assembly.

In a further development of this concept, the matrix material may be an epoxy resin.

According to a specific configuration of this concept, the uninsulated printed conductors may be configured to project out of the leadframe matrix.

According to an advantageous configuration of this concept, the printed conductors may be arrangeable in a housing, in order to permit the encapsulation thereof in a matrix, such that the combination of the housing and the leadframe matrix may be applied to a PCB.

In a further development of the concept, the combination of the housing and the leadframe matrix may be elastically bonded, and filled with an electrically-insulating soft resin mass.

The power module may include a carrier element, the underside of which is arranged on a metal layer, and the top side of which is fitted with a contact element, wherein a semiconductor component is positioned on the contact element. The semiconductor component may be configured as a small plate, with integrated contact points. The contact points of the semiconductor component are contacted on the top side by a leadframe matrix, by contact pressure, without the necessity for the execution of a sintering process, or a similar contacting process. The leadframe matrix is constituted of a plurality of mutually separated printed conductors, (e.g., printed copper conductors), which are encapsulated in a matrix material, (e.g., an epoxy resin). The uninsulated printed conductors project out of this leadframe matrix.

### BRIEF DESCRIPTION OF THE DRAWINGS

Further embodiments and advantages of the disclosure are described hereinafter with reference to the drawings.

FIG. 1 depicts a perspective representation of a semiconductor component with a contact point according to an embodiment.

FIG. 2 depicts a perspective representation of an electrical contacting arrangement between a leadframe and the contact points of the semiconductor component according to an embodiment.

FIG. 3 depicts a sectional representation of an electrical contacting arrangement between a leadframe and the contact points of the semiconductor component according to an embodiment.

FIG. 4 depicts a perspective representation of a leadframe matrix with a semiconductor component according to an embodiment.

### DETAILED DESCRIPTION

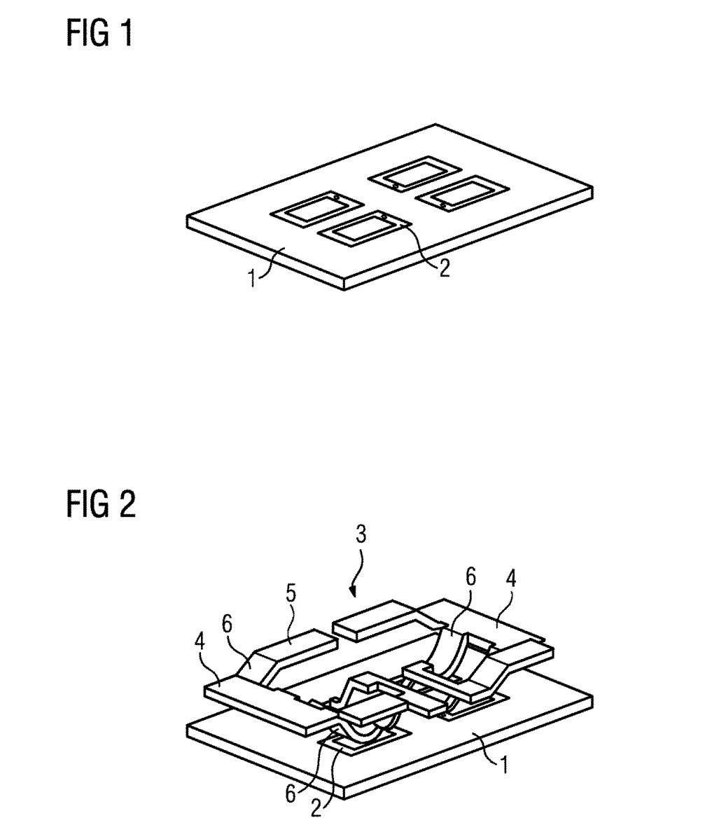

FIG. 1 represents a semiconductor component 1 in the form of a small plate, with contact points 2.

FIG. 2 depicts an electrical contacting arrangement between a leadframe 3 and the contact points 2 of the semiconductor component 1.

The leadframe 3 is constituted of a plurality of printed conductors 4, e.g., printed copper conductors. The printed conductors 4 are not configured in a planar design, in a single plane, but incorporate projections 5, which may interconnect two printed conductors 4 in different planes, by a bevel 6. The bevels 6 may also lead directly to the contact points 2.

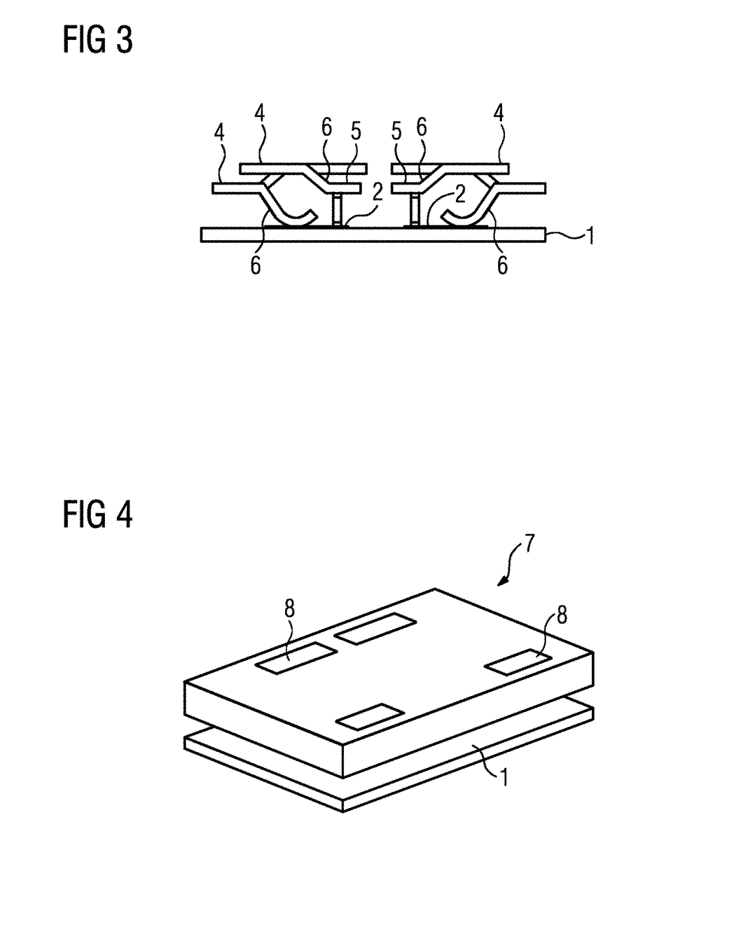

FIG. 3 depicts the representation according to FIG. 2. From FIG. 3, the bevel 6 either interconnects two projections 5 of the printed conductors 4 on different planes, or that the bevel 6 is routed to the contact point 2 of the semiconductor component 1.

FIG. 4 represents the leadframe matrix 7, with a semiconductor component 1. The printed conductors 4 may also be arranged in a housing, and encapsulated in a matrix, (for example, including an epoxy resin), such that the combination of the housing and the leadframe matrix 7 may be fitted to a PCB of the semiconductor component 1. The leadframe matrix 7, on its top side, includes contact points 8. On the underside, in the direction of the semiconductor component 1, spring contacts project out of the matrix material in the form of uninsulated printed conductors 4, in order to establish contact with the contact points 2 of the semiconductor component 1. Accordingly, the contact points 2 of the semiconductor component 1 are only contacted on the top side by a leadframe matrix 7 by the application of contact pressure.

The power module includes a semiconductor component, which is contacted on the top side by a leadframe matrix, is characterized in that the encapsulated leadframe matrix permits easy handling, as the mutually separated leadframe printed conductors are arranged in a matrix material. Moreover, the leadframe is protected by the matrix material, and may withstand small to moderate external forces. The robustness of the assembly is enhanced as a result. Additionally, it is not necessary for the leadframe to be directly pressed onto each individual chip. By the application of a specific pressure to the matrix material, the force is distributed evenly between the contact points. An advantage over the soldering or sintering of connecting elements is provided by the employment of standard chip surfaces. As a result, cost-effective semiconductors may be employed. Moreover, the leadframe is not permanently bonded to the chip, such that the latter is exempt from thermal stresses.

Although the disclosure has been illustrated and described in detail by the exemplary embodiments, the disclosure is not restricted by the disclosed examples and the person skilled in the art may derive other variations from this without departing from the scope of protection of the disclosure. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

1. A power module comprising:
a leadframe matrix; and
a semiconductor component configured to be contacted on a top side and an underside,
wherein the semiconductor component is to be electrically contacted on the top side by the leadframe matrix by contact pressure.

2. The power module of claim 1, wherein the leadframe matrix comprises a plurality of mutually separated printed conductors.

3. The power module of claim 2, wherein the printed conductors are printed copper conductors.

4. The power module of claim 3, wherein the printed conductors are encapsulated in a matrix material prior to assembly.

5. The power module of claim 4, wherein the matrix material is an epoxy resin.

6. The power module of claim 5, wherein uninsulated printed conductors are configured to project out of the leadframe matrix.

7. The power module of claim 2, wherein the printed conductors are arrangeable in a housing, and
wherein the printed conductors are encapsulated in a matrix such that a combination of the housing and the leadframe matrix are configured to be applied to a printed circuit board.

8. The power module of claim 7, wherein the combination of the housing and the leadframe matrix are elastically bonded and filled with an electrically-insulating soft resin mass.

9. The power module of claim 2, wherein the printed conductors are encapsulated in a matrix material prior to assembly.

10. The power module of claim 9, wherein the matrix material is an epoxy resin.

11. The power module of claim 10, wherein uninsulated printed conductors are configured to project out of the leadframe matrix.
